(19) United States
(12) Patent Application Publication
(10) Pub. No.: US 2023/0155414 A1
(43) Pub. Date: May 18, 2023

(54) Network for Distributing Electrical Energy

(71) Applicant: BKW Energie AG, Bern (CH)

(72) Inventor: Monika FREUNEK, New Brunswick (CA)

(21) Appl. No.: 17/911,266

(22) PCT Filed: Apr. 27, 2021
(86) PCT No.: PCT/EP2021/060982

§ 371 Date: Sep. 13, 2022

(30) Foreign Application Priority Data
Jul. 3, 2020 (CH) 00825/20

(51) Int. Cl. H02J 13/00; H02J 3/14; H02J 3/38

(52) U.S. Cl. CPC H02J 13/00004; H02J 3/144; H02J 3/381

(57) ABSTRACT

A network (1) for distributing electrical energy comprises a first network area (10) consisting of a plurality of local, self-regulating functional groups (11.1 . . . 8) having first sources, loads, lines and/or sensor, switching or converter components, wherein each of the functional groups (11.1 . . . 8) is designed for complying with assigned regulation limits for voltage quality variables in the network (1), and wherein the first network area (10) has a first size, and a second network area (20) having second sources, loads, lines and/or sensor, switching or converter components, wherein an estimated total variance of the voltage quality variables is assigned to the second network area (20), and wherein the second network area (20) has a second size. The regulation limits of the functional groups (11.1 . . . 8) and the first size are chosen such that, taking account of the second size and the estimated total variance, predefined target operating range limits for the entire network (1) are complied with.

### TECHNICAL FIELD

The invention relates to a network for distributing electrical energy. It furthermore relates to a computer-implemented method for structuring an existing network for distributing electrical energy, comprising as network components at least sources, loads, lines, sensor, switching and converter components, which are interconnected with one another in an initial topology, a method for operating a network for distributing electrical energy, and computer programs for carrying out the method for structuring and the method for operating.

### PRIOR ART

Networks for distributing electrical energy (electricity grids) comprise a network of electrical lines (namely overhead lines and underground cables) and further network components, which together with the lines are interconnected with one another in a specific topology. The further network components comprise sources, e.g. the generators of power plants, or temporary storage units such as e.g. batteries, loads (consumers), sensor components for capturing operating parameters of the network (voltages, frequency, currents, powers, temperatures, etc.), switching components for connecting and disconnecting components or network sections, and converter components, e.g. transformers, for example for changing the voltage.

The topology is subdivided into a plurality of network levels. Proceeding from a generator such as a power plant, the long-range distribution is effected firstly via a transmission network with an extra-high voltage (e.g. 380 or 220 kV). Substations with transformers are used to connect national distribution networks with a high voltage (e.g. 36-150 kV), to which regional distribution networks with a medium voltage (e.g. 1-36 kV) are in turn connected via further transformers. The local distribution network with a low voltage (e.g. 400 V-1 kV) is then connected via further transformers and leads (possibly via transformer stations) to the home connections and thus to the end consumer (inter alia private households, industrial plants, commercial enterprises and farms).

The specific topology having the components present in the network has grown historically depending on the locations and powers of the generators (power plants) and of the consumers. Changes to the topology generally require additional electrical lines or electrical lines which run or are dimensioned differently and are therefore costly.

In recent years, the requirements made of the electricity grid have changed—in particular on account of the advent of local generators such as e.g. photovoltaic installations. The electricity grid is no longer used merely for hierarchically distributing electrical energy “from the top” (i.e. from the power plant) “to the bottom” (i.e. to the consumers), rather the current flows may proceed differently depending on production conditions (e.g. insolation) and consumption patterns. In general, the production patterns of many renewable electricity generators are stochastic and associated with uncertainties. In this regard, e.g. the production powers of photovoltaic or wind power installations are greatly dependent on the weather. The future, short-, medium- and long-term development of the corresponding production capacities is not known and can be forecast only with difficulty because many of the corresponding installations are constructed by private and commercial producers that are independent of the previous electricity generators or network operators.

On the consumer side, too, decisive changes are arising. In particular, electric vehicles are leading to an increase in the power required at times, and their charging behavior is likewise stochastic and difficult to forecast.

Ultimately this results in an operating state of the electricity grid with chaotic behavior.

Furthermore, as climate change progresses this results in an increased risk of damage to exposed line sections, e.g. on account of forest or bush fires, storms, heavy precipitation events or landslides.

All this entails challenges in the planning and operation of failsafe electricity grids. An additional factor is that the present-day power supply networks of different operators are closely interlinked, and so problems in the network of a first network operator can lead to problems in networks of further operators in a cascade-like manner within a short period. This can lead to problems ranging from frequency compliance to power failures (blackout).

The control or regulation of the network, which is aimed at dependable operation and is namely intended to ensure that predefined regulation limits (e.g. with regard to frequency, voltage, current) are complied with, is generally hierarchically organized, which means that the requirements have increased greatly and more frequent interventions are needed to maintain operational dependability. In order to acquire further information, in particular on the consumer side, which can be included in the control or regulation, nowadays use is increasingly being made of so-called “smart meters”, which capture information, namely consumption information, directly from the consumers and transfer said information to superordinate devices of the network, e.g. a control center, via a communication network.

If control commands are then intended to be generated on the basis of a simulation and optimization, high-performance computers have to be used at this superordinate point in order to process information that is as comprehensive as possible without delay. This is also owing in particular to the huge volumes of data that arise and must be processed within a short period.

In addition to the enormous complexity for these calculations, such a centralized system also involves diverse fault sources. In this regard, the choice of the measures to be taken in the subordinate network section is complex, and there is a risk of operational disturbances in the event of faults in the communication of the measurement signals from the smart meters (and other sensor components) to the superordinate point or of the control signals back to the components in the network. Moreover, all potentially relevant information is hardly ever present because it concerns e.g. networks of neighboring network operators or privately operated electricity generating installations. The same applies to many consumers.

On the other hand, data comprising a large amount of redundant information are processed during the central data processing, and so ultimately the expenditure for the data processing includes an unnecessary high complexity with corresponding energy consumption.

EP 3 323 183 B1 (Siemens Aktiengesellschaft) relates to a method for the computer-aided control of the power in an electrical power supply network having a plurality of interconnected nodes, each containing a first energy generator and/or a second energy generator and/or an energy consumer. A power estimation is predefined for each node, said power estimation being composed of an estimation of the future load of the consumer or an estimation of the future power of the second, renewable energy generator in the node. Fluctuations of a first type and of a second type of the power estimations in predefined tolerance ranges are furthermore permitted, the fluctuations of a first type being compensated for by primary control power and the fluctuations of a second type being compensated for by secondary control power in the power supply network.

In the method described, an optimization problem is solved for the purpose of allocating the control powers, in the context of which optimization problem a steady state of the power supply network, with a steady-state network frequency, is modeled and the boundary conditions of which optimization problem comprise compliance with the network frequency within predefined tolerances and maximum powers on the power lines of the power supply network.

The method described requires a central control for a series of nodes in order to create sufficient degrees of freedom for the optimization. It is assumed that the estimation encompasses all the nodes and has a certain reliability. This gives rise to problems in practice because—as mentioned above—it is often the case that not all the information necessary for this is available and because dynamic changes arise on account of the stochastic behavior of many producers and consumers.

WO 2018/114404 A1 (BKW Energie AG) describes a method for structuring an existing network for distributing electrical energy, wherein the network comprises as network components at least sources, loads, lines, sensor, switching and converter components, which are interconnected with one another in an initial topology; in that method, on the basis of property variables of the network components and predefinable regulation limits, the network components are combined in a plurality of local, self-regulating functional groups. Each local functional group is assigned regulation processes comprising actions which are carried out upon the reaching of trigger criteria for complying with the regulation limits. The methods leads—proceeding from an existing network for distributing electrical energy—to a network which is reconstructed in respect of the regulation and which, with regard to the regulation, dispenses with a hierarchical structure as far as possible and instead is constructed from local functional groups which regulate themselves during normal operation. This results, inter alia, in a reduction of the susceptibility to faults and hence in an increase in the operational and supply dependability.

This approach makes it possible to avoid the disadvantages of the centralized approaches in the prior art. The structuring of an entire network by providing corresponding functional groups is complex, however, and additional measures have to be taken in order to limit influences from neighboring networks.

### SUMMARY OF THE INVENTION

It is an object of the invention to provide an electricity network which belongs to the technical field mentioned in the introduction and which enables a simple structuring with local functional groups and enables influences of neighboring networks and network sections to be systematically taken into account.

The way in which the object is achieved is defined by the features of claim 1. According to the invention, the network comprises
a) a first network area, consisting of a plurality of local, self-regulating functional groups having first sources, loads, lines and/or sensor, switching or converter components, wherein each of the functional groups is designed for complying with assigned regulation limits for voltage quality variables in the network, and wherein the first network area has a first size;
b) a second network area having second sources, loads, lines and/or sensor, switching or converter components, wherein an estimated total variance of the voltage quality variables is assigned to the second network area, and wherein the second network area has a second size;
   wherein the regulation limits of the functional groups and the first size are chosen such that, taking account of the second size and the estimated total variance, predefined target operating range limits for the entire network are complied with.

A local functional group within the meaning of the method according to the invention is formed by components interconnected with one another in accordance with a topology, where in the extreme case even a single network component can form a functional group. In this context, “local” does not necessarily mean that all the components of a functional group must be situated within a specific spatial region. If the latency of the transmission of information and the distance over which information has to be transmitted are taken into account when combining network components into functional groups, this should however generally result in all local functional groups being restricted to relatively small geographical areas in each case. In general, a functional group will comprise no “holes” and no regions isolated from the rest of the network components comprised.

Functional groups can be nested in one another, in principle, wherein an inner functional group can be regarded as a network component of the outer functional group.

The local functional groups regulate themselves during normal operation. They can be formed and operated in accordance with WO 2018/114404 A1 (BKW Energie AG), for example. In this regard, by means of respective actions of regulation processes assigned to the functional groups, measures outside the respective functional group can be triggered if trigger criteria are reached. The regulation processes can provide further actions which act only internally in functional groups. In principle, the term “regulation process” here denotes both interventions in the operation of network components and the transmission of specific information from one network component to specific other network components (in the same functional group, in a different functional group or at a superordinate or coordinate point).

For the self-regulation, the local functional groups comprise sensors (e.g. current or voltage sensors) actuators (e.g. switching or regulating devices for generators and/or loads) and control means (computers or controllers). The sensors are used in particular to check whether the assigned regulation limits are complied with. The control means trigger actions depending on the data captured by the sensors. Said actions can comprise in particular control actions by means of the driving of the aforementioned actuators and also communication actions with respect to coordinate or superordinate functional groups or instances with the aid of suitable communication means.

The functional groups enable a fast and local reaction. On account of the decentralized arrangement of the computation means, the volumes of data to be transferred to other functional groups or a superordinate logic are minimized, and complex central calculations are avoided. Moreover, a reduction of the communication times including latencies is achieved, as a result of which faster reactions are possible. The risk of a failure of a central control with wide reaching consequences is avoided. In the network according to the invention, the failure of a computer unit or of a communication channel has in general no, but at most little, influence on the overall stability of the network.

The sizes of the network areas can be characterized in various ways. One suitable measure is, for example, the average total amount of electricity in the corresponding network area. Other variables characterizing a total power or total capacity of the devices in a network area, for example, are likewise suitable. It can be assumed that the first network area and the second network area are constructed similarly, e.g. as far as the type and distribution of the consumers and producers are concerned, it is also possible simply to use the number of respective network components. Given a more or less homogeneous density of the network, the area respectively covered may also be sufficient.

The second network area is intended not to be empty. Moreover, it is also not structured like the first network area, that is to say that it is not constructed from local functional groups which regulate themselves in order to comply with assigned regulation limits. The second network area is, in particular, an existing, hierarchically controlled network having a network topology that grew historically, or a partial area thereof.

In the context of the network according to the invention, the first network area comprises in particular a plurality of functional groups, and a size of the second network area is at least one third, in particular at least half, of the first network area.

Voltage quality variables comprise for example the frequency, the network voltage (voltage level or root mean square value) or statistical and/or dynamic characteristic variables with regard to such parameters; current-related variables can also be used as voltage quality variables.

The target operating range limits can be defined with the aid of such voltage quality variables, target ranges generally being predefined for a plurality of such variables. Alternatively or additionally, other criteria can be used, e.g. maximum failure rates.

The uncertainty of the total network is thus shared between the supervised first network area and the non-supervised second network area. If the sizes of the first network area and of the second network area (or a ratio between these sizes) and the regulation limits for the first network area are then known, it is also possible to make a statement about the behavior of the corresponding voltage quality variables for the entire network. The topology and network capacities between the functional groups can be specifically taken into account or included as a fixed amount in the computation of the uncertainties.

On account of the available information concerning the first network area consisting of self-regulating functional groups, the uncertainty with regard to the second network area can be at least partly compensated for. In accordance with a simplified example, a voltage of at least 222 V is intended to be ensured in the network. In the first network area, a voltage of at least 224 V is ensured on account of the self-regulating functional groups, in particular because the minimum voltage is predefined as a regulation limit. The voltage quality in the first network area is thus always better than the predefinition for the entire network. If the ratio between the second size and the first size then does not exceed a specific ratio, the target value for the total network, including the not specifically regulated second network area, can be attained on account of the assured voltage quality in the first network area. The ratio between the variables which is to be complied with results from the estimated total variance of the voltage quality variable assigned to the second network area and the difference between the voltage quality ensured in the first network area and the predefinition for the entire network.

Worst case values are assumed for the estimation of the total variance of the voltage quality variable in the second network area. The estimation can be based on measured values, models and/or simulations. An improved estimation yields a lower total variance, which enables the following in the context of the network according to the invention:
a relaxation of the regulation limits in the first network area,
(theoretically) a reduction in size of the first network area and/or
an enlargement of the second network area through expansion of the system limits.

By way of example, machining learning approaches can be used for the modeling.

In addition to the local regulation of the functional groups in the first network area, the network according to the invention is distinguished by the fact that target operating range limits for the entire network, including a second network area without self-regulating functional groups, can be complied with. Accordingly, it is not necessary to restructure the entire network. Structuring only a part of the network with self-regulating functional groups and assigning stricter regulation limits to them may be more cost-effective than structuring the entire network with regulation limits that are somewhat less strict. It is thus possible firstly to structure e.g. those areas of a network in which this process is associated with the lowest costs, e.g. new network regions, network regions that will be renovated anyway, or network regions which are particularly well suited to the structuring on account of their existing structure. The availability of information may also be relevant when choosing the network area to be structured.

With the aid of a network according to the invention, strategically important network sections can be safeguarded, e.g. by the network according to the invention being designed such that particularly strict target operating range limits are satisfied.

Advantageously, the estimated total variance covers expected network operation during a time duration of at least one year. Seasonal fluctuations are thus concomitantly taken into account. The configuration of the network according to the invention is thus suitable for continuous operation and generally has to be adapted primarily in the following cases:
if relevant properties in the second network area change which result in a different estimated total variance;
if the second size changes.

A need for change also arises, of course, if deliberately new functional groups are created or functional groups are removed, if the system limits are changed or if the regulation limits for functional groups or the target operating range limits for the total network are changed.

In principle, it is possible to estimate the total variance in the second network area for a shorter period of time, e.g. if a network structure is intended to exist only during a limited period of time anyway or if the structuring of the network is updated at regular intervals (e.g. half-yearly).

Preferably, the network comprises at least one switching device in order to decouple the network from superordinate and/or coordinate further networks for distributing electrical energy.

Networks for distributing electrical energy, e.g. a network of a specific network operator or electricity supplier, are usually not isolated, but rather connected to further networks. With the aid of the switching device, excessively disturbing influences of neighboring networks can then be avoided as necessary by way of said networks being temporarily decoupled.

A coordinate further network can be a defined part of the distribution network of that operator which operates the network according to the invention. In this case, therefore, in addition to the first network area having self-regulating functional groups and the second network area, the total variance of which influences the dimensioning of the network according to the invention, there is also a third area, which can be decoupled from the first and second network area as necessary. This network thus lies outside the system limits of the network according to the invention, but cannot destabilize the latter, however, despite its linking to the two network areas, because it is able to be decoupled as necessary.

With the aid of the switching device, it is possible to ensure that the system limits taken into account for the definition of the functional groups, the regulation limits and the size of the first and second network area can actually always be complied with.

Preferably, a maximum extent of the functional groups is chosen such that a maximum signal propagation time within the functional groups is complied with. In the case of real-time-critical applications, switching times in the ms or even μs range should be possible, e.g. for switching actions in emergency situations or for trade. In practice such switching times can be achieved reliably only by means of a decentralized control or regulation such as takes place in the first network area in the context of the network according to the invention.

Proceeding from an existing network for distributing electrical energy, comprising as network components at least sources, loads, lines, sensor, switching and converter components, which are interconnected with one another in an initial topology, a network according to the invention can be created by means of a computer-implemented method for structuring which comprises the following steps:
a) capturing the existing network within predefined system limits;
b) capturing regulation limits for local, self-regulating functional groups;
c) capturing target operating range limits for the structured network to be created;
d) carrying out an optimization of a target function by varying network properties, wherein
e) the variable network properties comprise at least one assignment of network components to one of a plurality of local functional groups of a first network area or an assignment of network components to a second network area,
f) a total variance of voltage quality variables is estimated for the second network area;
g) wherein what is predefined as boundary condition for the optimization is compliance with the target operating range limits, the checking of which is effected taking account of the regulation limits of the functional groups, a first size of the first network area and a second size of the second network area and the total variance of the second network area.

An “existing network” can be a section of a larger network. In principle, the user can stipulate the field of application of the method, i.e. which network components are actually intended to be taken into account.

A “source” within the meaning of the method according to the invention can be a generator, a (current-outputting) battery or some other energy storage unit or simply an “input” of the network or network section under consideration. “Loads” within the meaning of the method are consumers, batteries or other energy storage units in the charging mode or simply an “output” of the network or network section under consideration. Depending on the operation state of the network, certain network components can at times constitute sources or loads. There are likewise network components which combine a plurality of functions (e.g. load and sensor component, source and converter components, etc.).

The existing network can be represented by means of a topology with supplementary indications; indications concerning the geographical location of the network components and/or a network plan are/is likewise information concerning the existing network which can be captured in the context of the method. The system limits are also initialized by the capture of the existing network. They can optionally also be adapted later—as described further below.

The captured regulation limits relate both to the present regulation limits of already existing functional groups and to regulation limits which are to be complied with by functional groups to be created. The capture of the existing network thus involves concomitantly capturing possibly already defined functional groups including present regulation limits and further characteristic variables. However, the method can also be applied if no functional groups have been defined yet within the system limits.

In the context of the variation of the network properties, the network components can be assigned both to an existing functional group and to a newly formed functional group. The number of functional groups is thus variable. This also applies to the size of the first network area and the size of the second network area, which change in the case of an assignment of a network component of the second network area to a functional group, that is to say a transfer of a network component from the second network area into the first network area.

The variable network properties can also comprise the regulation limits for one, a plurality or all of the functional groups, thereby enabling a comprehensive optimization of the entire network within the system limits, taking account of the predefined boundary conditions. The presence and/or the positioning of (additional) switching and control devices for existing consumers and/or generators can likewise be part of the variable network properties.

During the estimation of the total variance in the second network area, individual partial regions of the second network area can be treated specially, e.g. those for which more detailed information is available or which are known to be distinguished by a comparatively low variance. These also include transition zones which have already been partly adapted in the context of a restructuring of the network.

Capturing steps a)-c) do not have to be carried out in the indicated order. A plurality of the indications to be captured can originate from the same data source; it is also possible to generate individual items of information to be captured by means of the combination of data from a plurality of data sources.

The optimization is, in particular, an optimization with the aid of a numerical optimization method, e.g. a method of linear optimization. Suitable algorithms comprise e.g. simplex methods or interior point methods. On account of the complexity of a distribution network and the many degrees of freedom, the optimization cannot be carried out without using computer-aided numerical analysis.

Advantageously, crude data sets are used in the context of the numerical optimization only where this is unavoidable. Otherwise the optimization is preferably based on data sets obtained by machine learning on the basis of high-quality historical data.

In one preferred embodiment of the method, the total variance of the voltage quality variables for the second network area is estimated on the basis of historical operating data.

The historical operating data can comprise, in particular, the temporal profile of the current (in a balance-related way or over three phases), the voltage (in a balance-related way or over three phases) and/or the electrical power (in a balance-related way or over three phases).

If the estimated total variance is intended to permanently cover expected network operation, the historical operating data relate to a time duration of at least one year. Seasonal fluctuations can thus be concomitantly taken into account. The fluctuations from year to year can additionally be taken into account by using longer time series and/or by means of estimations, preferably with the aid of corresponding data-supported computer-implemented simulation and measurement methods.

In addition to the historical operating data, further information can influence the estimation, for example information about the network topology and the network components and/or results of model calculations or simulations. In this regard, it is possible, for example, to assign reference profiles to the network components, worst case estimations being used in the case of doubt.

In an alternative embodiment, the use of historical operating data is dispensed with. In this case, the estimation is based on simulations and/or model calculations.

Advantageously, the variable network properties comprise a presence and/or a positioning of an additional switching device for selectively decoupling a part of the second network area and/or an additional device for power and/or voltage limiting. With the aid of such switching device, the network to be structured can be automatically optimized with regard to its system limits as well. The switching devices can also be used for decoupling superordinate networks or third-party networks. The devices for power and/or voltage limiting can likewise protect the network to be structured or parts thereof against external influences. With the aid of the switching devices and/or the devices for power and/or voltage limiting, it is possible to ensure that the system limits defined or obtained in the context of the optimization can actually always be complied with.

Advantageously, the variable network properties comprise a presence and/or a positioning of an additional storage installation and/or an additional production installation. In this regard, the first network area, in particular, which is constructed from self-regulating functional groups, can be automatically extended. By taking account of the costs of additional storage and/or production installations, it is ensured that the solution found in the context of the optimization is also advantageous from an economici standpoint—additionally installations such as these are thus proposed only if the structuring cannot be realized straightforwardly in some other way.

In the case of the positioning of the storage and/or production installations and the assignment to functional groups, in particular signal propagation times and the capacities of the lines are concomitantly taken into account.

Advantageously, the variable network properties comprise an extension of the predefined system limits. By way of example, both initial system limits and maximum system limits are predefined during the initialization of the method according to the invention, the maximum system limits encompassing e.g. all networks which are within the area of influence of the network operator. If the target variable can then be better attained by means of an extension of the system limits in the context of the optimization, the system limits are extended—within the scope of the maximum system limits. By way of example, network components outside the initial system limits can be integrated into existing functional groups or functional groups to be newly created.

Preferably, during the process of capturing the existing network, the predefined system limits can be chosen such that the network encompassed already complies with the target operating range limits, after which the system limits are iteratively extended until compliance is no longer possible or other boundary conditions are contravened.

The optimization is carried out in each iteration step, further network components being assigned. Existing and/or possible additional switching devices are concomitantly taken into account.

Even if the existing network, within the system limits, does not yet comply with the target operating range limits, the iterative extension can still be effected in a later phase, after an optimization within the system limits.

Alternatively, the system limits are fixedly predefined. They can be changed by the user during the initialization of the method in order to check different scenarios.

Advantageously, maximum communication times between a plurality of functional groups can be predefined as further boundary condition for the optimization. Complying with maximum communication times ensures that the regulation limits are complied with again within the necessary period. Furthermore, regulation of the network as locally as possible is fostered.

Advantageously, a maximum communication time within a functional group is likewise predefinable as boundary condition. This has the effect that functional groups that are as local as possible and can react rapidly to changing requirements are formed in the context of the optimization.

In the case of the assignment to functional groups, the number thereof, their geographical location, the number of neighbors and further parameters can furthermore be taken into account.

Advantageously, the target function is dependent on a volume of data transferred between the network components for regulating the network, and the optimization fosters a minimization of said volume of data.

This criterion, too, results in a network that is regulated as locally as possible. Moreover, a reduction of the transferred volume of data with a predefined error rate results in a smaller absolute number of errors. The disturbance rate in the total network is thus reduced.

Advantageously, the target function is dependent on costs of an adaptation between the existing network and the structured network to be created, and the numerical optimization fosters a minimization of said costs. The costs of the adaptation include costs for additional network components.

The target function can be dependent on further criteria, e.g. on local prices for the local functional groups (nodal pricing). A further optimization criterion can be the saving of CO₂, where it should be taken into consideration that additional actuators, sensors, computation installations, etc., constitute an additional CO₂ limit. In this respect, on account of the local processing of sensor data and the reduction of data transferred over long distances, the method according to the invention is advantageous anyway by comparison with conventional centralized approaches. The invention can thus also be used to achieve CO₂ targets by means of optimal use of operating equipment.

With the aid of the method according to the invention, it is possible if necessary directly also to minimize the number of functional groups required within predefined system limits in accordance with WO 2018/114404 A1 (BKW Energie AG).

A computer-implemented method for operating a network for distributing electrical power comprises the following steps:
a) in a first network area, operating a plurality of local, self-regulating functional groups having first sources, loads, lines and/or sensor, switching or converter components, such that each of the functional groups complies with assigned regulation limits for voltage quality variables in the network;
b) operating second sources, loads, lines and/or sensor, switching or converter components of a second network area, such that a total variance of voltage quality variables in the second network area is complied with;
   wherein
c) the first network area has a first size and the second network area has a second size; and
e) the regulation limits of the functional groups and the first size are chosen such that, taking account of the second size and the total variance, predefined target operating range limits for the entire network comprising first and second network areas are complied with.

For the self-regulation, the local functional groups comprise sensors (e.g. current or voltage sensors) actuators (e.g. switching or regulating devices for generators or loads) and control means (computers or controllers). The sensors are used in particular to check whether the assigned regulation limits are complied with. The control means trigger actions assigned to the functional group for complying with the regulation limits depending on the data captured by the sensors. Said actions can comprise in particular control actions by means of the driving of the aforementioned actuators and also communication actions with respect to coordinate or superordinate functional groups or instances with the aid of suitable communication means.

The sizes of the network areas can be characterized in various ways. One suitable measure is, for example, the average total amount of current in the corresponding network area.

The second network area is intended not to be empty. Moreover, it is also not structured like the first network area, that is to say that it is not constructed from local functional groups which regulate themselves in order to comply with assigned regulation limits. The second network area is, in particular, an existing, network having a network topology that grew historically.

Voltage quality variables comprise for example the frequency, the network voltage (voltage level or root mean square value) or waveform-related variables; current-related variables can also be used as voltage quality variables.

The target operating range limits can be defined with the aid of such voltage quality variables, target ranges generally being predefined for a plurality of such variables. Alternatively or additionally, other criteria can be used, e.g. maximum failure rates.

In principle, in the context of operation, the present structuring of the network into the first network area and the second network area and the structuring of the first network area into local functional groups can be checked periodically or constantly. It is thus immediately recognized whether, on account of changed boundary conditions, a change in the division into network areas and/or the assignment to functional groups and/or an adaptation of regulation processes would be expedient. Such a change can then be implemented at a suitable point in time.

Advantageously, compliance with the predefined target operating range limits is monitored and at least one device for limiting a power fed to the functional groups is actuated in the case of non-compliance with the target operating range limits. The device can form part of a functional group and limit the power fed to this functional group from outside. It can also be superordinate to functional groups and limit the power fed to a plurality of functional groups up to the entire first network area.

In the short term, excess power can be dissipated by means of components such as resistance heating units. On somewhat longer time scales, storage units (inter alia charging devices, super caps and batteries) can also be used.

Advantageously, at least one switching device for decoupling the network from superordinate and/or coordinate further networks for distributing electrical energy and/or at least one switching device for decoupling a part of the second network area are/is actuated in the case of non-compliance with the target operating range limits. The decoupling is effected particularly if the measures for power limiting reach their limits and regulation-conforming operation of the network can no longer be ensured even with such measures.

A decoupling (island operation) can also be expedient in other situations, e.g. if energy can be prevented from being carried away toward the outside.

With the aid of the switching devices, it can be ensured that the system limits defined or obtained in the context of the optimization can actually always be complied with.

A computer program according to the invention for carrying out the method according to the invention for structuring an existing network for distributing electrical energy or respectively for operating the network according to the invention is adapted in such a way that it carries out a corresponding method when it is executed on a computer. The computer program will generally comprise a plurality of components which, under certain circumstances, are executed on different processors of a distributed computer system.

Further advantageous embodiments and combinations of features of the invention are evident from the following detailed description and the totality of the patent claims.

### BRIEF DESCRIPTION OF THE DRAWINGS

In the drawings used for elucidating the exemplary embodiment:

FIG. 1 shows a schematic illustration of a network according to the invention for distributing electrical energy;

FIG. 2A shows the profile of a voltage quality variable in a period of time in the first network area and in the second network area; and

FIG. 2B shows the profile of the voltage quality variable in the period of time in the entire network.

In principle, identical parts are provided with identical reference signs in the figures.

Ways of Embodying the Invention

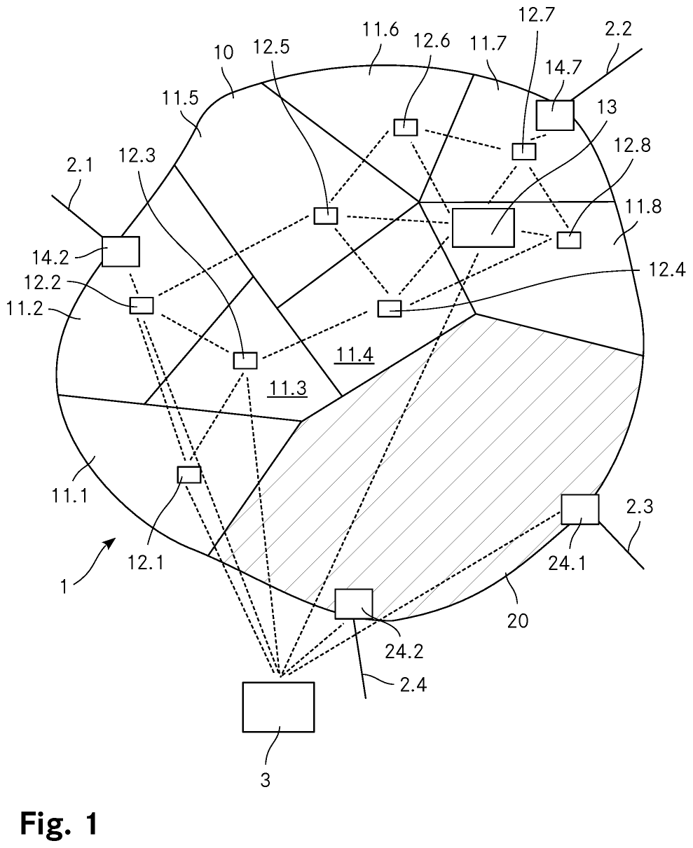

FIG. 1 is a schematic illustration of a network 1 according to the invention for distributing electrical energy. Said network comprises a first network area 10, which is structured in eight largely self-regulating functional groups 11.1 . . . 8 in accordance with the teaching of WO 2018/114404 A1 (BKW Energie AG), and a second network area 20 without such a structuring. The network has four connecting lines 2.1 . . . 4 to coordinate, superordinate and/or subordinate further networks. A connecting line 2.1 emerges from the second functional group 11.2, a further connecting line 2.2 emerges from the seventh functional group 11.7, two further connecting lines 2.3, 2.4 emerge from the second network area 20.

As known from WO 2018/114404 A1, the functional groups 11.1 . . . 8 each comprise a plurality of elements of the network and components connected thereto, namely sources, loads, lines, sensor, switching and converter components. Each of the functional groups 11.1 . . . 8 comprises a computer unit 12.1 . . . 8 (symbolized by a rectangle). This can be an independent unit, a dedicated microprocessor arranged at a component, or an existing element of a component. Each of the functional groups 11.1 . . . 8 illustrated likewise contains at least one sensor unit (not illustrated here) which measures one or more relevant variables and communicates same to the corresponding computer unit 12.1 . . . 8. Some of the functional groups 11.1 . . . 8 additionally contain actuators, by means of which the functioning of the respective functional group 11.1 . . . 8 can be influenced in a manner triggered by the respective computer unit 12.1 . . . 8.

In the example illustrated, five functional groups 11.4 . . . 8 are interconnected to form a cluster. This means that a cluster computer unit 13 is also present in addition to the local computer units 12.4 . . . 8, and is connected to the local computer units 12.4 . . . 8 in order to exchange signals.

The computer units 12.1 . . . 8 of neighboring functional groups 11.1 . . . 8 are likewise connected to one another for the exchange of signals and can exchange information when corresponding actions are triggered. In the example illustrated, there are the following connections:

| RE | 12.1 | 12.2 | 12.3 | 12.4 | 12.5 | 12.6 | 12.7 | 12.8 |
|---|---|---|---|---|---|---|---|---|
| 12.1 | | X | X | | | | | |
| 12.2 | X | | X | | X | | | |
| 12.3 | X | X | | X | | | | |
| 12.4 | | | X | | X | | | X |
| 12.5 | | X | | X | | X | | |
| 12.6 | | | | | X | | X | |
| 12.7 | | | | | | X | | X |
| 12.8 | | | | X | | | X | |

Both the computer units 12.1 . . . 3 of the functional groups 11.1 . . . 3 that are not connected to the cluster and the cluster computer unit 13 are additionally connected to a central computer 3. The latter forms a control center; in contrast to conventional networks, however, said control center, with regard to the first network area, is required only as an exception if the functional groups cannot resolve an event themselves.

The connections illustrated should be understood as examples. The illustration does not mean that (direct) physical connections between the stated components must exist; data can be exchanged by way of an arbitrary network topology between the components.

As illustrated in detail in WO 2018/114404 A1, functional groups can extend over a plurality of network levels and comprise converters, inter alia.

In order then, if necessary, to be able to decouple individual functional groups or the entire network from further networks, a respective switching device 14.2, 14.7, 24.1, 24.2 is arranged at all the connecting lines 2.1 . . . 4. The connection can be temporarily disconnected by means of said switching device. Two switching devices 14.2, 14.7 are respectively assigned to the corresponding functional group 11.2, 11.7 and are controlled by the corresponding computer unit 12.2, 12.7. Two further switching devices 24.1, 24.2 in the second network area are controlled directly by the central computer 3.

Each of the functional groups 11.1 . . . 8 represents a network section (i.e. a continuous region of the network with assigned network components) having specific properties with regard to measurement variables and measurement range and optionally regulability. Regulation limits, i.e. target ranges of the variables to be regulated, are assigned to each functional group 11.1 . . . 8.

For target operation, rules, possible actions and required information are assigned to each of the functional groups 11.1 . . . 8 in order to be able to check whether trigger criteria for the actions have been satisfied. In order to define the regulation limits, there is an orientation to existing components and/or to standards (for instance maximum permissible current for a cable) or for instance—in the case of a new construction—to the connections and a requested maximum power.

The projections of the future powers are effected for instance by means of customary methods of network planning, but in particular with the use of simulations and modellings and machine learning.

Each action comprises one or more measures, in particular the activation of an actuator and/or the sending of a message to other components. The actions are assigned to the individual functional groups. If actions concerning a plurality of functional groups are defined, actions can also be assigned to specific combinations of functional groups (interconnected with one another).

The following table lists, for example, parameters for target operation in a local distribution network. The action listed in the last column is respectively carried out if the operating range is not complied with, i.e. a corresponding trigger criterion is satisfied:

| | | Lower | | Upper | | |
|---|---|---|---|---|---|---|
| | | operating | | operating | | |
| Unit | Parameter | range | | range | | Action |
| PV meter with | Frequency | 49.5 | Hz | 50.5 | Hz | Reduce P_{active}, disconnect |
| control output | | | | | | from the network starting |
| and interrupter | | | | | | from 52 Hz |
| PV meter with | Voltage | 207 | V | 253 | V | Obtain reactive power, |
| control output | | | | | | reduce power if that does not |
| and interrupter | | | | | | suffice |
| PV meter with | Current | 0 | A | 100 | A | Disconnect from the |
| control output | | | | | | network/change tariff/send |
| and interrupter | | | | | | message |

| | | | | |
|---|---|---|---|---|
| PV meter with | Harmonics | 0 | 20 | Store number of times the |
| control output | | | | value is exceeded; if more |
| and interrupter | | | | than 10, send message to |
| | | | | network operator/connect |
| | | | | short-circuit current amplifier |
| | | | | or filter/contact customer and |
| | | | | change tariff |

| | | Lower | Upper | | |
|---|---|---|---|---|---|
| | | operating | operating | | |
| Unit | Parameter | range | range | Rule | Action |
| Meter for | Voltage, | EN 50160 | EN 50160 | Action when | Reduce voltage |
| customers | Current | 0 | X | the time | to the lowest |
| with a | | | | information | value according |
| moderate, | | | | is acquired | to EN50160 if |
| temporally | | | | | the load limit is |
| limited load | | | | | exceeded |
| limit | | | | | |
| Meter for | Current | 0 | X | Comply | Limit current |
| customers | | | | with upper | to the upper |
| with load | | | | operating | operating range |
| limit | | | | range | |

Further possible actions comprise, for example, the temporal shift of the operation of consumers or of the charging of storage units or the temporal control of the production output of producers or of the discharging of storage units.

The communication is effected with first priority within a given functional group, with second priority between functional groups or in the cluster, and only with third priority to the central computer, i.e. to the control center.

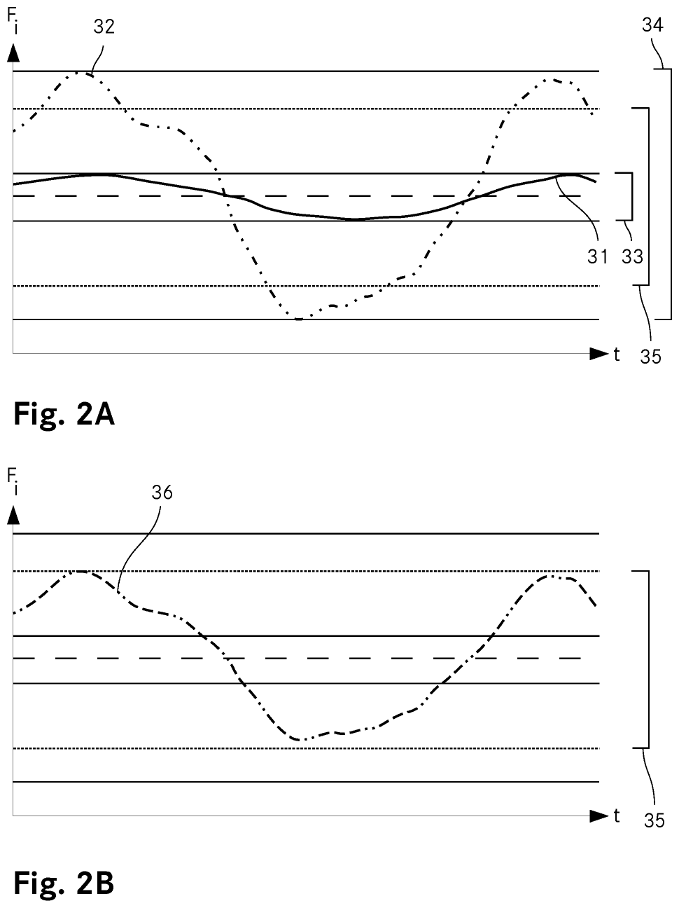

FIG. 2A shows the profile of a voltage quality variable in a period of time in the first network area and in the second network area. FIG. 2B shows the profile of the voltage quality variable in the period of time in the entire network.

The state of a network for distributing electrical energy is defined by the temporal profiles of voltage quality variables, e.g. of the phasewise voltages, phasewise currents and phases. These temporal profiles can be represented by a time-dependent vector-valued function F(t) with components Fᵢ(t).

In existing networks, both the function F(t) and the variances of the individual component functions are largely unknown. Since the function F ultimately arises from a multiplicity of subfunctions for individual components of the distribution network concerning which complete information is not available, in practice it is also difficult to reproduce the function F(t).

Mathematically, therefore, the system described cannot be completely captured. Approaches for making the stochastic behavior more calculable can only partly solve this basic problem, inter alia because the system is not totally closed and so the number and characteristics of not all subfunctions of F(t) are known.

In the context of the invention, it is accordingly proposed to carry out the following steps:
1. The distribution network characterized by the function F(t) is assigned a maximum allowed variance s(F(t)), within which the supply dependability and/or other optimization parameters are/is ensured within the scope of a predefined confidence range. The parameters that are correspondingly to be complied with can arise from a legal predefinition, e.g. for the permissible voltage and/or frequency ranges. The corresponding target range 35 for a component Fᵢ is illustrated in FIGS. 2A, 2B. It should be noted that the target variable and/or the width of the target range may be temporally variable depending on the voltage quality variable.
2. Let F(t)=k(t)+m(t), where k(t) covers all devices in a first network area, which is structured by self-regulating functional groups in accordance with WO 2018/114404 A1 (BKW Energie AG). Since regulation limits are assigned to these functional groups, reliable statements concerning the variance can be made for k(t). m(t) covers a second network area, which is not structured by self-regulating functional groups with predefined regulation limits. On the basis of historical data and/or simulations or model calculations, an expected maximum variance can be assigned to m(t). The total variance s(F(t)) then results from the variances s(k(t)) and s(m(t)). FIG. 2A illustrates the profile 31 for the voltage quality variable Fᵢ in the first network area and the profile 32 for the voltage quality variable Fᵢ in the second network area, these profiles being based on the assumption that the individual network areas are operated independently of one another (i.e. are not coupled to one another). The corresponding fluctuation bands 33, 34 are likewise illustrated. It is evident that in this case the predefinitions (target range 35) are not complied with in the second network area.
3. Since the predefinitions in the first network area are overfulfilled, a profile 36 of the voltage quality variable Fᵢ in the total network which complies with the predefinitions in accordance with target range 35 arises when the two network areas are coupled together (cf. FIG. 2B).
4. In the context of an optimization, the factors underlying k(t) and m(t) can then be varied, the predefinitions in accordance with target range 35, e.g. the maximally tolerable fluctuation of the frequency and/or (if known) of the power and/or voltage tolerance bands per network level, being set as boundary condition. The factors include, in particular, the assignment of network components to functional groups: if further network components are assigned to a functional group, the size of the second network area becomes smaller, and the estimated variance (s(m(t)) accordingly decreases. In addition, the contribution to the variance s(k(t)) of the first network area can be calculated reliably. Further variables concern the regulation limits assigned to the functional groups, the addition of additional components (sources, loads, switching devices, etc.), the extension or restriction of the system limits, etc. Optionally, certain production or consumption powers (e.g. of storage power plants, heat stores or batteries) are allocated a temporal flexibility as optimization variable.

In this case, the optimization can serve for establishing the network, i.e. proceeding from an existing network in which local self-regulating functional groups are not yet defined, or for further development of said network, i.e. proceeding from a network that is already (partly) structured accordingly. An iterative procedure can be adopted here: the procedure begins with a core cell. If the result is satisfactory and permits latitude, the area can be extended in a further optimization step.

In an extended implementation, simulations and models of technological developments such as increases in efficiency or progressive reductions of costs can also be incorporated into an optimization run. In this case, a run would not comprise one reference year, but rather a plurality thereof.

For the (numerical) optimization in step 4 a target function is defined. The latter includes the desired optimization parameters of the total system. The optimization can be carried out with regard to the following optimization targets:

a) minimizing the number of functional groups required;

b) proximity of the position of the functional groups to predefined positions or areas;

c) minimizing the costs for stable operation;

d) minimizing the regulation limits of existing functional groups.

The corresponding parameters can be optimized in relation to one another. The weighting is dependent on the targets of the user, generally an energy supplier, the regulatory possibilities thereof, the importance of economic factors and geographical limitations, if present.

In addition to the above-mentioned boundary condition for the network stability, the following boundary conditions, inter alia, can influence the optimization:

a) limitations of the transmittable powers, e.g. on account of cable cross sections;

b) maximum allowed signal transmission time and resulting maximum possible distance between functional groups in order to be able to communicate with one another and carry out as necessary switching action, regulation interventions or commercial transactions;

c) maximum allowed signal transmission time, resulting therefrom the maximum possible distance between one, a plurality or all of the functional groups and another unit, such as the central computer, for instance, in order to communicate with one another and to be able to carry out as required switching actions, regulation interventions or commercial transactions;

d) temporal restrictions, for instance for power shifts or limitations;

e) geographical/topological conditions (exclusion of specific areas or definition of specific areas as functional groups);

f) economic criteria;

g) regulatory criteria.

Regulation processes ultimately include the determination of one or more measurement variables, the processing for determining the action(s) to be taken, and the performance of the action up to the influencing of the regulation variable. Depending on the complexity of the regulation process, the distribution of the participating components in the network and the time needed for the processing of the measurement variables, a certain signal transmission time results. The maximum signal transmission times need not be the same for all regulation processes because certain instances of regulation have to take place more rapidly than others if the intention is for operation of the network not to be adversely influenced. By means of a comparison with the smallest information latencies physically possible, it is possible, however, to immediately eliminate specific scenarios which are not compatible with the required communication times (taking account of the latencies), e.g. the real-time control of a Smart Grid by means of Smart Meters if “real time” is in the seconds range or if data are transmitted only once a day (e.g. from the household meter) and “real time” means a maximum of 10 min.

With the aid of suitable boundary conditions, it is thus possible to ensure, inter alia, that the network found in the context of the optimization can actually function physically in that powers to be compensated for can be transmitted in the required time frame and without the overloading of lines (and if necessary further components). Strategically positioned functional groups may be essential precisely in respect of voltage stability. Under certain circumstances, therefore, it is not sufficient just to keep the total variance within a predefined range. With the aid of the technical boundary conditions mentioned, in such cases in the context of the optimization regions in the system arise in which at least one self-regulating functional group is intended to be arranged.

In order that the optimization can take place, the following information is thus provided:

a) topological information of the network within the initial or maximum system limits, for instance in the form of a network plan, including network components and switching devices present if necessary; such information can be obtained e.g. from a network-related geographical information system (GIS);

b) indications concerning the system limits—the corresponding choice can be made via a graphical interface in a manner known per se, e.g. by the parts of the network that are to be taken into account being selected or parts that are not to be taken into account being deselected: a restriction to certain network levels is also possible;

c) number and properties of the self-regulating functional groups already present in the network (including size indications, e.g. a temporal balance total of the power in a reference time period and also regulation limits);

d) per functional group: temporal profile of the current (in a balance-related way or over three phases) over a chosen reference time, e.g. one year, voltage (in a balance-related way or over three phases) over a chosen reference time, e.g. one year; alternatively electrical power (in a balance-related way or over three phases) over a chosen reference time, e.g. one year;

e) maximum allowed tolerances, e.g. with regard to the frequency and/or voltage, generally or at specific network positions;

f) environment information and weighting factors: technical factors, costs for technologies, energy prices, electricity tariffs, other economic factors.

For generating the temporal profiles, it is possible to use historical data from production and consumption or data from models and simulations that model for instance a generator type and the locally typical profile of an environmental variable or a consumer type. Physical limitations, e.g. on account of installed transformers or production installations, can likewise influence the estimation. In a preferred implementation, models are linked with historical data and machine learning to form reference profiles and adjusted more accurately as necessary, for instance by means of a production or consumption profile adapted to regional conditions and habits. This can encompass—for consumption—for instance holidays or work times and break habits and—for production—maximum possible photovoltaic production on the basis of global radiation data and available areas and the orientation thereof.

With the aid of statistical methods such as, for instance, use of the theory of random sampling, the quality of these estimations can be further refined to their reliability as “historical tolerance band” and be implemented.

Customary numerical optimization methods, e.g. simplex or interior points methods, are suitable for the optimization. The numerical optimization is computationally complex on account of many degrees of freedom. Since it does not determine the ongoing operation of the network, but rather the structure thereof, the optimization step is not time-critical, however. The computational complexity can be limited by reducing the considered or maximum system limits or by dispensing with certain degrees of freedom (e.g. with regard to the existing functional groups or with regard to measures that are associated per se with high implementation costs).

The optimization yields the following variables, inter alia:

a) number of self-regulating functional groups, indications concerning the corresponding assignment of the network components;

b) costs associated with the structuring and/or the operation of the network;

c) the allowed tolerance bands to be predefined for the functional groups;

d) necessary communication, control and regulating units in functional groups, central control units and at the system limits.

Depending on the objective, the method according to the invention for structuring can be used in various ways:
1. if an energy supplier would like to protect itself for example against the chain reactions of unforeseen major events in the network, the energy supplier will strive for a system in which island operation is possible in the case of an emergency. At the same time, however, the costs of the adaptations are intended to be minimized
Proceeding from a network which already has some functional groups, strategically important functional groups are localized in the context of the optimization and are added to the structure. Particularly narrow tolerance bands are assigned to these functional groups in order to keep the number of functional groups small. The control center is equipped with a communication interface to selected functional groups. The lines of the system limits are retrofitted with communication and control technology. Some functional groups are equipped with communication, control and regulation technology.
2. If an energy supplier wants primarily to optimize its trade, in particular with renewable energy, and make it more plannable, the energy supplier will strive to ensure that trade quotas are known at an early stage and reliably available.
Proceeding from a network which already has some functional groups, the number and nature of the functional groups still required in order to attain stable trade forecasts are identified in the context of the optimization. A centralized or decentralized control device (e.g. the control center or a comparable device) is equipped with a communication interface to selected functional groups. Trade is equipped with a communication interface to selected functional groups and/or the control device. Some or all functional groups are equipped with communication, control and regulation technology.

During the operation of the network according to the invention, the individual functional groups of the first network area regulate themselves as far as possible. If this is no longer possible without violating the regulation limits in the context of a functional group, proceeding from the functional group the communication with other functional groups and/or superordinate points takes place according to a predefined scheme with a plurality of escalation levels. Different schemes can be predefined for different functional groups. In practice, in particular the physical limits with regard to the signal propagation times should be taken into account.

When a plurality of functional groups are combined to form a cluster (virtual functional group), the regulation takes place with first priority within the individual functional groups, with second priority within the cluster and only with third priority, if mutual compensation among the cluster functional groups is no longer possible, with the participation of further functional groups or components.

In its simplest form, a trigger criterion is formed by a predefined value of a variable and by an indication of whether the criterion is satisfied if the value of an input variable (e.g. of a measurement variable) is exceeded or undershot. However, a trigger criterion can also be defined by a range indication or can be based on a more complex function, which in particular also includes logical (Boolean) operators. A trigger criterion can relate to a present value of the input variable or of a plurality of input variables, or a certain past interval of time is taken into account. Trigger criteria can additionally be dependent not only on the variables assigned to the respective regulation limit but also on a rate of change of such variables (that is to say specifically the time derivative). In this regard, a rapid increase or a rapid decrease in a variable can already indicate that there is a need for action before the regulation limits are reached.

By way of example, if the functional group A has too little power on account of an unusually high volume of electric automobiles and below average PV production, a local computer unit of the functional group A sends a request signal to the local computer unit of the neighboring functional group B. The functional group B communicates the power available in the short term and in the medium term. At the request of the functional group A, the functional group B then releases the power required in the short term. The functional group A accepts the power. Since the power does not provide coverage in the medium term, the functional group B sends a signal to a communication interface of a virtual functional group C. The latter is formed by the interconnection of the functional groups D-G, the functional group E of which contains, inter alia, a relatively large hydroelectric power plant. The communication interface of the virtual functional group C sends a signal to the functional group E, containing, inter alia, the required production power for the expected period of time. The functional group E sends confirmation to the communication interface, and the latter to the functional group A and/or B. The functional group A finally accepts the power.

In another scenario, in the area of the functional group A a storm has destroyed a utility pole. The functional group A recognizes this as a disturbance and transmits an emergency call to a superordinate control center to schedule an engineer. At the same time, the functional group A requests the omitted power from the neighboring functional group B at the highest priority level.

The functional group B extends its tolerance range up to a maximum permissible value and regulates its regulable loads, storage units and production installations in such a way that the required power can be delivered. Since ultimately not all the requested power can be provided within the functional groups A and B or individual (non-critical) consumers have to be switched off or regulated for reduction, both the local computer unit of the functional group A and the local computer unit of the functional group B send a signal to a communication center or to a locally stored list in order that customers are informed about a disturbance with slight impairments.

On the basis of the method according to the invention for structuring the network, operation in which the system limits thereof vary depending on the operating situation can also be effected. If, for instance, it is too expensive for an energy supplier immediately to plan and to operate the entire network according to the present patent, it is possible to begin with a core area which consists of self-regulating functional groups and is physically disconnectable from the rest of the area as necessary.

In addition to the core area there may be transition zones which have in part already been optimized in respect of stability but are not yet in a state of being able to be operated fully autonomously. For such transition zones, it is possible as necessary for portions of m(t) or s(m(t)) to be estimated more precisely, such that the estimated variance s(m(t)) is reduced.

In general, it will be necessary to decouple the optimized and operated area from adjacent conventionally operated networks if the latter jeopardize defined target operation and stabilizing measures within the system limits considered in the context of the optimization are not sufficient.

This is done using the switching devices 14.2, 14.7, 24.1, 24.2 (see FIG. 1), which are actuated in an automated manner or, if appropriate, after a corresponding recommendation of the system has been received, are actuated manually, and/or control and regulating devices. If these are already present, in the context of the optimization, a check is made to ascertain whether supplementations are necessary, for instance by communication links. Otherwise the type, number and dimensioning of the available disconnecting switches and control and regulating devices are output variables.

In a corresponding scenario, disturbances occur in a network as a result of influences outside the system limits of the optimized system, with the result that the necessary tolerances in respect of phase, frequency, voltage or power can no longer be complied with. Severe equipment damage, production losses, failures of critical infrastructures or a black out are imminent. A plurality of functional groups communicate signals about the contraventions of the tolerance limits to the control center and/or among one another. As soon as a functional group and/or the control center have/has received or calculated a specific critical value, a control or regulating command for power regulation or decoupling is sent to some or all of the system limits and executed.

Analogously, in the context of operation of the network according to the invention with regard to optimization of costs and/or trade, it is also possible to implement price-led power release and production and charging control.

In summary, it can be stated that the invention provides a systematically implementable method for structuring a network for distributing electrical energy which is individually adaptable to predefined boundary conditions, and furthermore a distribution network with high supply dependability and a method for operating same.

1. A network for distributing electrical energy, comprising
a) a first network area, consisting of a plurality of local, self-regulating functional groups having first sources, loads, lines and/or sensor, switching or converter components, wherein each of the functional groups is designed for complying with assigned regulation limits for voltage quality variables in the network, and wherein the first network area has a first size;
b) a second network area having second sources, loads, lines and/or sensor, switching or converter components, wherein an estimated total variance of the voltage quality variables is assigned to the second network area, and wherein the second network area has a second size;
wherein the size of the first network area and the size of the second network area (20) are characterized on the basis of one of the following variables:
an average total amount of current in the network area;
a total power of the devices in the network area;
a total capacity of the devices in the network area;
a number of network components in the network area;
a covered area of the network area; and
wherein the regulation limits of the functional groups and the first size are chosen such that, taking account of the second size and the estimated total variance, predefined target operating range limits for the entire network are complied with.

2. The network as claimed in claim 1, wherein the estimated total variance covers expected network operation during a time duration of at least one year.

3. The network as claimed in claim 1, wherein at least one switching device in order to decouple the network from superordinate and/or coordinate further networks for distributing electrical energy.

4. The network as claimed claim 1, characterized in that wherein a maximum extent of the functional groups is chosen such that a maximum signal propagation time within the functional groups is complied with.

5. A computer-implemented method for structuring an existing network for distributing electrical energy, comprising as network components at least sources, loads, lines, sensor, switching and converter components, which are interconnected with one another in an initial topology, for creating a network as claimed in claim 1, comprising the following steps:
a) capturing the existing network within predefined system limits;
b) capturing regulation limits for local, self-regulating functional groups;
c) capturing target operating range limits for the structured network to be created;
d) carrying out an optimization of a target function by varying network properties, wherein
e) the variable network properties comprise at least one assignment of network components to one of a plurality of local functional groups of a first network area or an assignment of network components to a second network area,
f) a total variance of voltage quality variables is estimated for the second network area;
g) wherein what is predefined as boundary condition for the optimization is compliance with the target operating range limits, the checking of which is effected taking account of the regulation limits of the functional groups, a first size of the first network area and a second size of the second network area and the total variance of the second network area, wherein the size of the first network area and the size of the second network area are characterized on the basis of one of the following variables:
an average total amount of current in the network area;
a total power of the devices in the network area;
a total capacity of the devices in the network area;
a number of network components in the network area;
a covered area of the network area.

6. The method as claimed in claim 5, wherein the total variance of the voltage quality variables for the second network area is estimated on the basis of historical operating data.

7. The method as claimed in claim 5, wherein the variable network properties comprise a presence and/or a positioning of an additional switching device for selectively decoupling a part of the second network area and/or an additional device for power and/or voltage limiting.

8. The method as claimed in claim 5, wherein the variable network properties comprise a presence and/or a positioning of an additional storage installation and/or an additional production installation.

9. The method as claimed in claim 5, wherein the variable network properties comprise an extension of the predefined system limits.

10. The method as claimed in claim 9, wherein during the process of capturing the existing network, the predefined system limits are chosen such that the network encompassed already complies with the target operating range limits, after which the system limits are iteratively extended until compliance is no longer possible or other boundary conditions are contravened.

11. The method as claimed in claim 5, wherein maximum communication times between a plurality of functional groups are predefined as further boundary condition for the optimization.

12. The method as claimed in claim 5, wherein the target function is dependent on a volume of data transferred between the network components for regulating the network, and in that the optimization fosters a minimization of said volume of data.

13. The method as claimed in claim 5, wherein the target function is dependent on costs of an adaptation between the existing network and the structured network to be created, and in that the numerical optimization fosters a minimization of said costs.

14. A computer-implemented method for operating a network for distributing electrical energy, comprising the following steps:
a) in a first network area, operating a plurality of local, self-regulating functional groups having first sources, loads, lines and/or sensor, switching or converter components, such that each of the functional groups complies with assigned regulation limits for voltage quality variables in the network;
b) operating second sources, loads, lines and/or sensor, switching or converter components of a second network area, such that a total variance of voltage quality variables in the second network area is complied with;
wherein
c) the first network area has a first size and the second network area has a second size, wherein the size of the first network area and the size of the second network area are characterized on the basis of one of the following variables:
an average total amount of current in the network area;
a total power of the devices in the network area;
a total capacity of the devices in the network area;
a number of network components in the network area;
a covered area of the network area; and wherein
e) the regulation limits of the functional groups and the first size are chosen such that, taking account of the second size and the total variance, predefined target operating range limits for the entire network comprising first and second network area are complied with.

15. The method as claimed in claim 14, wherein compliance with the predefined target operating range limits is monitored and at least one device for limiting a power fed to the functional groups is actuated in the case of non-compliance with the target operating range limits.

16. The method as claimed in claim 15, wherein at least one switching device for decoupling the network from superordinate and/or coordinate further networks for distributing electrical energy and/or at least one switching device for decoupling a part of the second network area are/is actuated in the case of non-compliance with the target operating range limits.

17. A computer program for carrying out the method as claimed in claim 5.

18. A computer program for carrying out the method as claimed in claim 14.
